(19) United States
(12) Patent Application Publication
(10) Pub. No.: US 2008/0103616 A1
(43) Pub. Date: May 1, 2008

(54) Holder Identifying Apparatus, Component Supplying Method And Mounter

(76) Inventor: Akifumi Wada, Fukuoka (JP)

Correspondence Address: WENDEROTH, LIND & PONACK L.L.P., 2033 K. STREET, NW, SUITE 800, WASHINGTON, DC, 20006, US

(21) Appl. No.: 11/663,645

(22) PCT Filed: Jan. 12, 2006
(86) PCT No.: PCT/JP06/00678

§ 371 Date: Mar. 23, 2007

(30) Foreign Application Priority Data
Jan. 19, 2005 (JP) 2005-011895

(51) Int. Cl. H05K 13/04

(52) U.S. Cl. 700/95; 29/729

(57) ABSTRACT

A holder identifying apparatus (140), which is detachably fitted to a mounter (100) that obtains components (500) from component holders for supplying the components (500) and that mounts the components (500) onto a board, and is used together with at least one component holder (150), includes a holder information storage unit (443) which stores information regarding the component holder (150).

### TECHNICAL FIELD

The present invention relates to a holder identifying apparatus to be applied to a mounter for mounting components onto a board.

### BACKGROUND ART

A conventional mounter for mounting components onto a board has multiple component holders as represented by tape feeders and parts feeders which are detachably fitted to a mounter body, and mounts various types of components which are held and supplied in a predetermined order by the respective component holders.

Such component holder holds, in a component tape, a large number of components of the same type placed sequentially in a row in a length direction of the holder. In the case where a component needs to be supplied, the component holder winds off the component tape and takes off the cover, so that a component is placed in a position from which the component should be picked up.

The operation of the component holder is controlled mainly by the mounter body using only ON-OFF signals based on an assignment of dots to respective pins of a connector connecting the mounter body and the component holder.

A recent tendency, however, especially in the field of mounters mounting electric components onto a board is that plural types are provided for a width of a component tape intended for holding electrical components, and also, a pitch of placing components into a tape is not specified. In addition, a mounter is required to mount multiple types of electric components with high speed and high precision. Such requirement necessitates a component holder to improve accuracy in placing a component in a position from which the component should be picked up, and to be flexibly adaptive to the types of the components as well as the types of the tapes. This increases demand for high-control over such component holder.

The Japanese Laid-Open Application No. 2003-124688 can be taken as an example of the reference describing a component holder that is highly controllable.

The tape feeder described as such component holder in the above-mentioned reference includes, as shown in FIG. 1, a memory which stores data for identifying a type of the self-holding components and a method of supplying the components, so that the data is provided to a mounter body via communication.

The mounter body obtains the data stored in the memory of the tape feeder, and compares, with a table obtained by the mounter body, control information indicating sending pitch and speed as well as the types of the electric components held in each of the tape feeders equipped to the mounter. The mounter body then sends a control command corresponding to the data of a tape feeder. A control unit equipped in each component holder interprets the control command so as to highly control the tape feeder.

### DISCLOSURE OF INVENTION

However, in the case where a company manufacturing mounters passes an order of component holders such as the tape feeder as described above to another company, the manufacturing company has to disclose, to that company, a communication specification (e.g. control command) used for a communication between a mounter and a component holder. Such communication specification is closely related to an operation of a mounter, and therefore, the disclosure of the communication specification may expose the operation procedure and the method of controlling the mounter to the risk of being decrypted. Technical know-how is also included in the communication specification so that the communication specification is to be kept secret as much as possible to other companies. Thus, the disclosure of communication specification to other companies shall be strictly prevented.

The present invention is conceived in view of the above problem, and an object of the present invention is to provide a holder identifying apparatus which can perform high control over a component holder that can perform communication compliant only with a general specification without disclosing a communication specification used for the communication with a mounter.

In order to achieve the above object, the holder identifying apparatus according to the present invention is a holder identifying apparatus detachably fitted to a mounter which obtains components from component holders for supplying the components, and mounts the components onto a board, and includes: a holder information storage unit operable to store holder information regarding one of the component holders; and a communication unit operable to communicate with a mounter body regarding the information stored in the holder information storage unit, wherein the holder identifying apparatus is used together with the component holder.

Thus, the component holder which is used together with the holder identifying apparatus for combined use does not need to directly exchange information with the mounter, and thus does not need to disclose a communication specification to an order destination even in the case of contracting out the component holders. The type of the component holder can be flexibly changed only by rewriting the information stored in the holder information storage unit.

The holder identifying apparatus may further include a control unit operable to send and receive, to and from the component holder, a control signal through a communication compliant with a predetermined specification, based on a control command from the mounter body.

Thus, the component holder installed in the holder identifying apparatus does not need to directly receive a control command from the mounter and is controlled based on the communication specification predetermined for the communication with the holder identifying apparatus. It is therefore possible to highly control the component holder without disclosing a communication specification to an order destination even in the case of contracting out the component holders.

The specification may specify that that bits should be assigned to respective signal lines intended for control.

The holder identifying apparatus may further include a fitting unit operable to detachably fit the holder identifying apparatus to an attaching/detaching part to which the component holder is fitted.

Thus, a positional relationship between the holder identifying apparatus and the component holder installed therein can be easily and visually checked in the state where the both are equipped to the mounter. This reduces the operator's burden of checking if the apparatus and the holder are set properly and prevents them from being inappropriately installed.

The holder information storage unit may further store collective information for collectively specifying plural component holders.

Thus, the component holders which supply components of various types or components of the same type can be recognized at once, so that the component holders can be easily controlled with less number of components.

The above object can be achieved not only by the holder identifying apparatus as described above, but also by a mounter installed in such holder identifying apparatus, and even by a component supplying method applied by the mounter.

It is possible to highly control the component holder that can perform communication compliant only with a general specification without disclosing the communication specification used for the communication with the mounter.

For further information about technical background to this application, the disclosure of Japanese Patent Application No. 2005-011895 filed on Jan. 19, 2005, including specification, drawings and claims is incorporated herein by reference in its entirety.

### BRIEF DESCRIPTION OF DRAWINGS

These and other objects, advantages and features of the invention will become apparent from the following description thereof taken in conjunction with the accompanying drawings that illustrate a specific embodiment of the invention. In the Drawings:

FIG. 1 is a block diagram showing a conventional component holder;

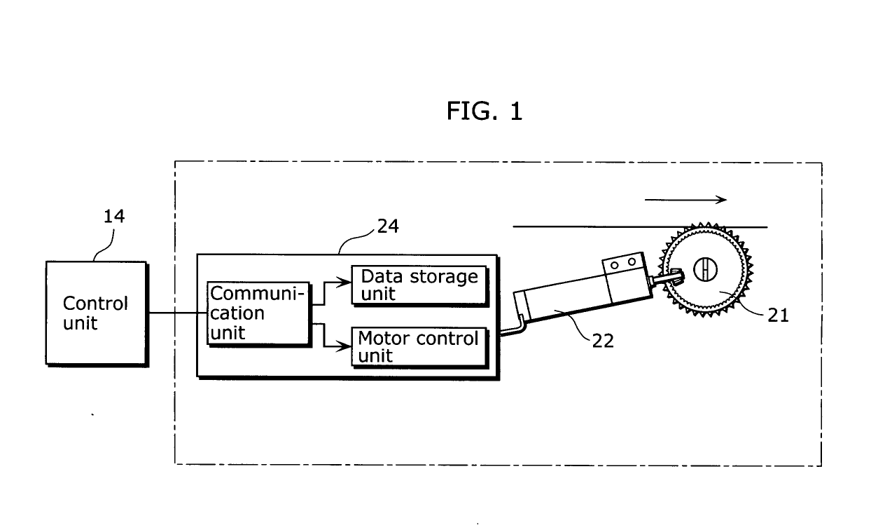

FIG. 2 shows an appearance of the entire structure of a mounter according to the present embodiment;

FIG. 3 is a planar view showing a main structure of the mounter;

FIG. 4 shows an appearance of a holder identifying apparatus: (a) shows its lateral view, and (b) shows its front view;

FIG. 5 is a block diagram showing functional structures of the holder identifying apparatus, a mounter body and a parallely-used feeder;

FIGS. 6A through 6D respectively shows an example of the electric components to be mounted;

FIG. 7 is a diagonal view showing a component tape in which the electric components are held, and a supply reel for supplying the components;

FIG. 8 is a lateral view of the parallely-used feeder;

FIG. 9 is a lateral view showing a component feeder carriage for supplying components, the parallely-used feeder and the holder identifying apparatus;

FIG. 10 is a lateral view showing how to equip the parallely-used feeder and the holder identifying apparatus onto the component feeder carriage;

FIG. 11 is a front view showing how the holder identifying apparatus and the parallely-used feeder are connected;

FIG. 12 is a planar view showing a state in which the holder identifying apparatus and the parallely-used feeder are equipped onto the mounter body;

FIG. 13 is a sequence diagram showing the operations of the mounter body, the holder identifying apparatus and the parallely-used feeder;

FIG. 14 is a front view showing a placement relationship between the holder identifying apparatus and the parallely-used feeder which are not connected;

FIG. 15 shows the mounter according to a variation of the embodiment: (a) shows its lateral view, (b) shows its front view, and (c) shows a lateral view of the holder identifying apparatus; and

FIG. 16 also shows the mounter according to another variation of the embodiment: (a) shows its lateral view, (b) shows its front view and (c) shows a lateral view of the holder identifying apparatus.

### BEST MODE FOR CARRYING OUT THE INVENTION

The following describes the embodiment of the present invention with reference to the diagrams.

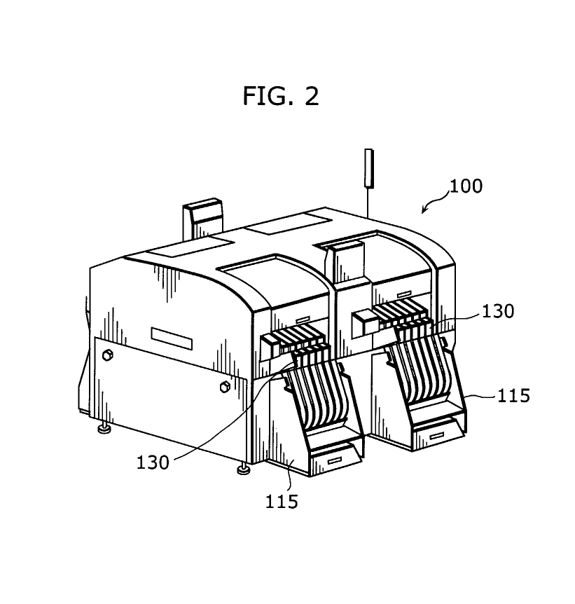

FIG. 2 is a diagonal view showing an appearance of the entire structure of a mounter 100 according to the present invention. The mounter 100 can form a production line for mounting electric components while transferring a circuit board (board) from an upper stream toward a lower stream.

The mounter 100 includes a component supplying unit 115 for supplying a mounter body 101 with the electric components to be mounted on a circuit board. The component supplying unit 115 has, as component holders, an array of plural tape feeders 130, each sending out a component tape as a component holder, or an array of plural parts feeders 130, each sending out the components held in a cassette.

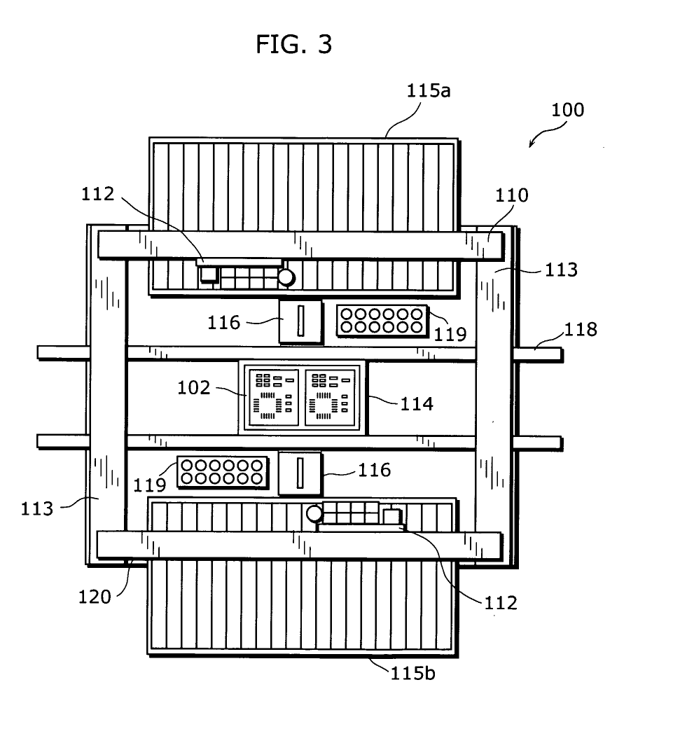

FIG. 3 is a planar view showing a main structure of the mounter 100 of the present embodiment.

As shown in the diagram, the mounter 100 includes two sub facilities (a front sub facility 110 and a rear sub facility 120) which work in cooperation for mounting components onto a circuit board. Each of the sub facilities 110 and 120 functions as an orthogonal robot-type mounting stage, and includes a multi mounting head 112, an XY robot 113, a component recognizing camera 116, a board transferring unit 118 and a nozzle station 119.

The multi mounting head 112 has plural suction nozzles (hereinafter to be simply referred to as “nozzle”) which can simultaneously pick up plural electric components supplied by the component supplying unit 115, and mount them onto a circuit board 102.

The XY robot 113 moves, freely and with high speed, the multi mounting head 112 in a horizontal direction.

The component recognizing camera 116 is used for two- or three-dimensionally examining the state in which the electric components are picked up by the multi mounting head 112.

Thus, each sub facility works in cooperation with the other sub facility so as to mount the components onto one circuit board.

The board transferring unit 118 transfers the circuit board 102 to a mounting table 114 used for mounting the electric components held by the multi mounting head 112.

The nozzle station 119 is a table on which nozzles to be exchanged for mounting different types and forms of components are placed.

Note that “component tape” is actually a tape (e.g. carrier tape) on which components of the same type are placed, and the components are supplied in a state of being wound around a supply reel (intended for component supply) or the like. Such component tape is used mainly for supplying the components of relatively small size called “chip components” onto a mounter. The components supplied as such that is held in the component tape is called “taping components”.

To be more specific, the mounter 100 is a mounter equipped with the functions of a mounter called “high-speed mounter” and a mounter called “multi-function mounter”. The high-speed mounter is characterized by its capability of mounting, with high productivity, an electric component as tiny as 10 mm or less, whereas the multi-function mounter is characterized by its capability of mounting a large-sized electric component of 10 mm or greater, an odd-shape component such as a switch and a connector, and IC components such as a Quad Flat Package (QFP) and a Ball Grid Array (BGA).

In other words, the mounter 100 is designed to be capable of mounting almost all types of electric components (including a chip resistance with the size of 0.4 mm×0.2 mm and a connector with the size of 200 mm), and a production line can be formed by arranging such components mounter 100 as many as necessary.

After passing the component recognizing camera 116, the multi header 112, having picked up the components supplied by the component supplying unit 115a or 115b, moves to a mounting point on the circuit board 102 placed on the mounting table 114 and repeats the process of mounting until all the picked-up components are mounted.

Here, the “mounting point” is a coordinate point on the board onto which the components are to be mounted. The component of the same type may be, in some cases, mounted on a different mounting point.

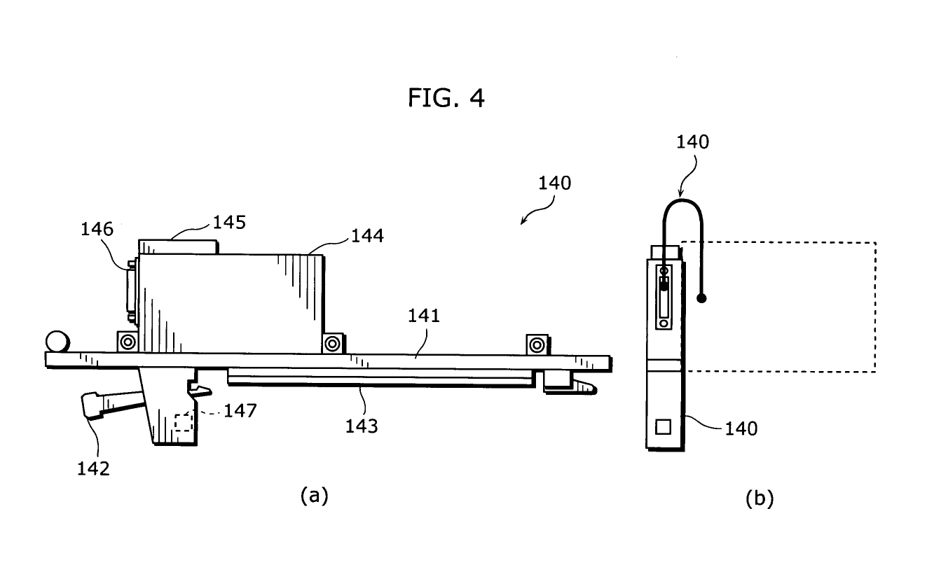

FIG. 4 shows an appearance of the holder identifying apparatus: (a) shows its lateral view, and (b) shows its front view.

As shown in the diagram, the holder identifying apparatus 140 includes a supply base 141 which serves as a fitting unit and has the same form as the tape feeder so that the supply base 141 is fitted to the component supplying unit 115. A fixing lever 142 for fixing the component supplying unit 115, and a rail 143 or the like are equipped to such supply base 141. A holder identifying apparatus body 144 includes a switch 145 which can give a simple instruction to the mounter body 101, a connector 146 which connects, via a communication cable, the body 144 and a parallely-used feeder 150 which will be mentioned later as a feeder used in combination with the holder identifying apparatus 140, and a connector 147 which connects, via a communication cable, the holder identifying apparatus 140 and the mounter body 101. Note that a connector compliant with a general specification, e.g., a Dsub 69 pin, a Dsub 15 pin and a DIN terminal, can be used as the connector 146.

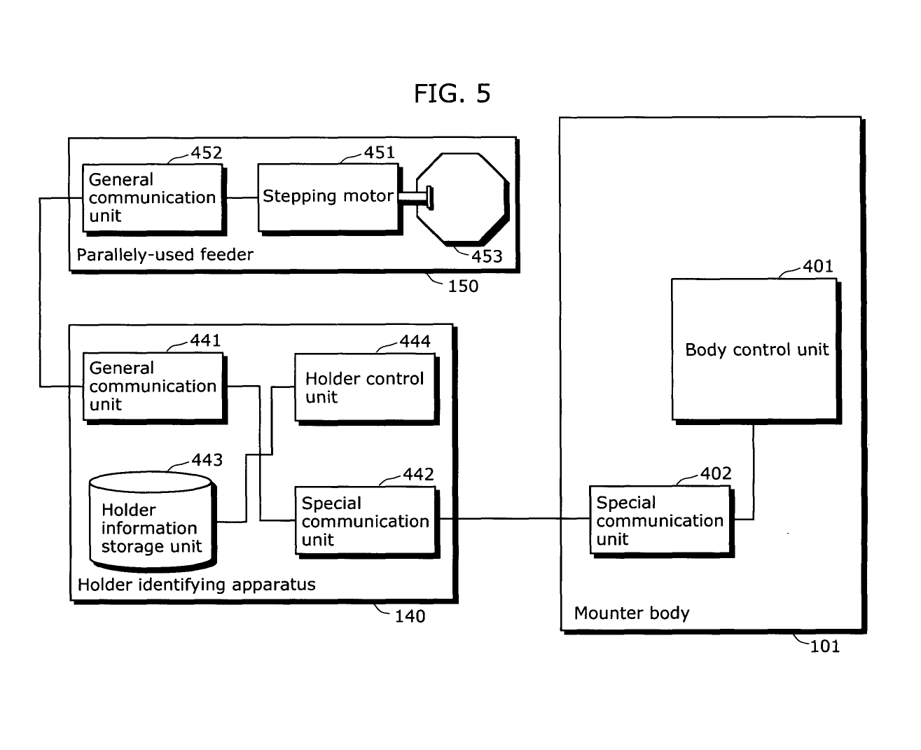

FIG. 5 is a block diagram showing functional structures of the holder identifying apparatus 140, the mounter body 101 and the parallely-used feeder 150.

As shown in the diagram, the holder identifying apparatus 140 is an apparatus that serves as intermediary between the parallely-used feeder 150 and the mounter body 101, and includes a general communication unit 441, a special communication unit 442, a holder information storage unit 443 and a holder control unit 444.

The general communication unit 441 is a control unit for performing a communication, in compliance with a general specification, with the parallely-used feeder 150. The “general specification” here is a communication specification that is already disclosed to the public, and the examples of such specification are input/output, PS2 (DOS/V) and ECHONET which specify that bits should be assigned to respective pins of a connector.

The special communication unit 442 is a control unit for performing a communication, in compliance with a special specification, with the mounter body 101. The “special specification” is a command-based communication specification used for the communication between the mounter body 101 and the holder identifying apparatus 140.

The holder information storage unit 443 is a storage medium such as a semiconductor memory for storing the information regarding the parallely-used feeder 150 to be fitted to the component supplying unit 115 together with the holder identifying apparatus 140 for combined use. Such holder information storage unit 443 stores information such as management information of the parallely-used feeder 150 (e.g., name, number, ID and operation timing of the parallely-used feeder 150, and information about how many slots the parallely-used feeder 150 occupies, where a slot is an attaching/detaching part), enable/disable information (e.g., key code) indicating whether or not the parallely-used feeder 150 can be mounted (controlled for mounting) onto the mounter body 101, information on types and numbers of the electric components to be fed by the parallely-used feeder 150, information regarding the number of electric components to be supplied and the number of components that remain, and information for preventing a wrong setting of components and information for history management.

The holder control unit 444 is a control unit which controls, via the general communication unit 441, a stepping motor 451 for feeding the component tape set in the parallely-used feeder 150. Such holder control unit 444 receives, via the special communication unit 442, a command which is sent from the control unit 401 of the mounter body 101 during the command-based communication, and interprets the command so as to control the parallely-used feeder 150.

The parallely-used feeder 150 includes a general communication unit 452 for performing a communication, in compliance with the general specification, with the holder identifying apparatus 140, a stepping motor 451, and a feed gear 453 for feeding the component tape that is driven by the stepping motor 451.

The general communication unit 452, in some cases, merely functions as a connector for connecting the stepping motor 451 and the holding identifying apparatus 140, depending on the communication specification.

The mounter body 101 includes a body control unit 401 and a special communication unit 402. The body control unit 401 is a processing unit which (1) overall controls the processing of mounting the components, (2) obtains, from the holder identifying apparatus 140, all the information such as positions and a supply specifications of the respective tape feeders or parts feeders, and the types of electric components, and (3) gives instructions, to the holder identifying apparatus 140 via the special communication unit 402, on the timing in which a tape feeder should be moved to a predetermined position and the timing in which the component feeder should feed the electric components to be supplied, depending on a circuit board onto which the electric components are to be mounted.

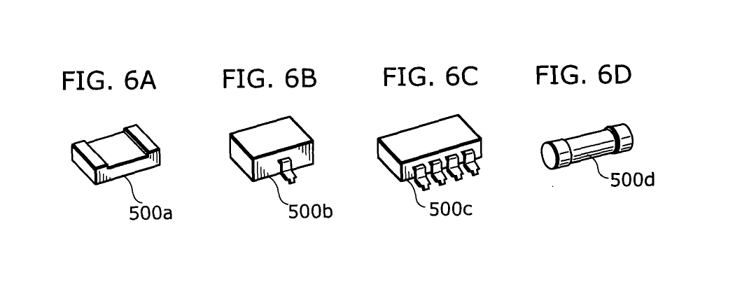

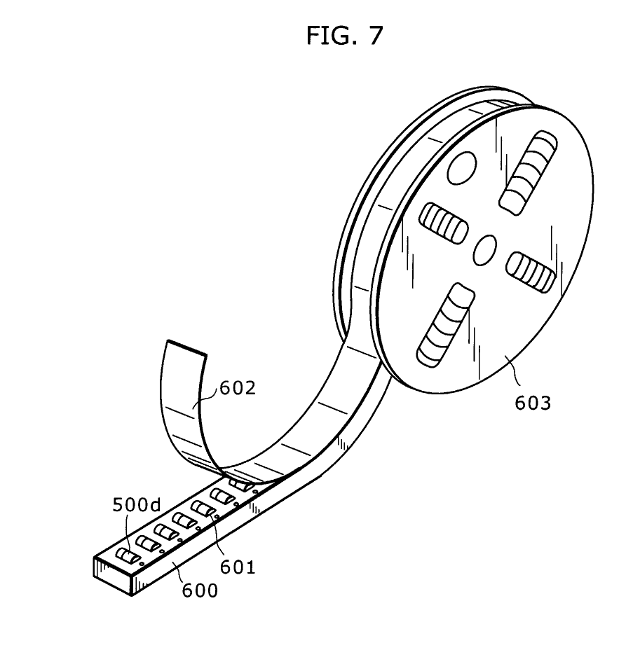

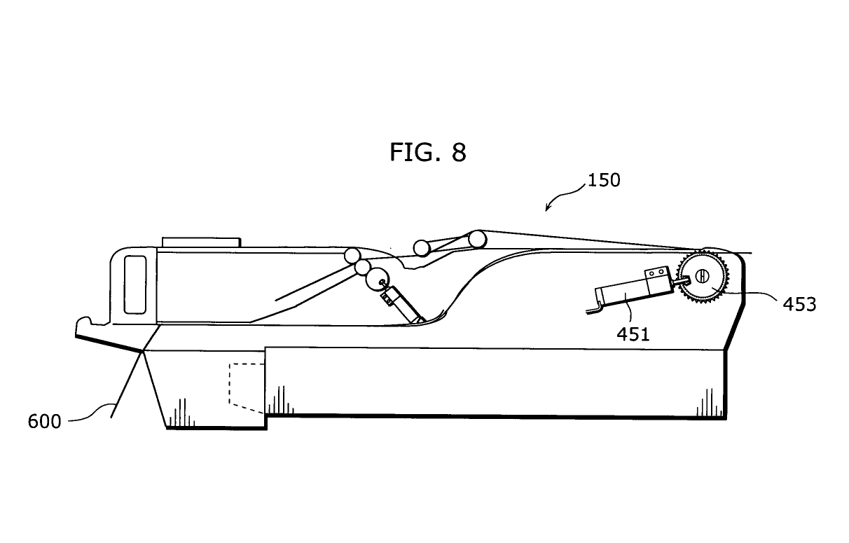

The following describes in detail a structure of the parallely-used feeder 150, with reference to FIGS. 6 through FIG. 8. FIGS. 6A through 6D respectively shows an example of the electric components to be mounted. FIG. 7 shows examples of the component tape in which the electric components are held, and the supply reel intended for component supply. FIG. 8 is a lateral view of the parallely-used feeder 150.

The various chip electric components 500a through 500d shown in FIGS. 6A through 6D are held in concave holders 601 sequentially formed at regular intervals in a carrier tape 600 shown in FIG. 7, and are packed in such a manner that the top is covered by a covering tape 602. The carrier tape 600 thus covered by the covering tape 602 is supplied to the user in the state of being wound around a supply reel 603 for a predetermined number of windings. However, the form of the holder for holding electric components is not limited to a concave form. The component tape is made up of such carrier tape 600 and covering tape 602, and the component tape 600 and the supply reel 603 function as one of the component holders for holding electric components.

The components tape is not limited to the carrier tape 600 as shown in FIG. 7, and a pressure sensitive adhesive tape or a paper tape onto which components are fixed can be used instead.

FIG. 8 shows the parallely-used feeder 150. The appearance of the parallely-used feeder 150 is not so much different from that of a general tape feeder. The parallely-used feeder 150 is not so different from the general tape feeder also in that it introduces the carrier tape 600 from the supply reel 603 that is externally set, and supplies the electric components 500 by peeling off the covering tape 602 while feeding the carrier tape 600 by the feed gear 453. The difference lies in that the parallely-used feeder 150 neither includes a control unit which controls the stepping motor 451 nor a storage unit which previously stores information about a tape feeder.

Next, the description of how to set the holder identifying apparatus 140 and the parallely-used feeder 150 follows.

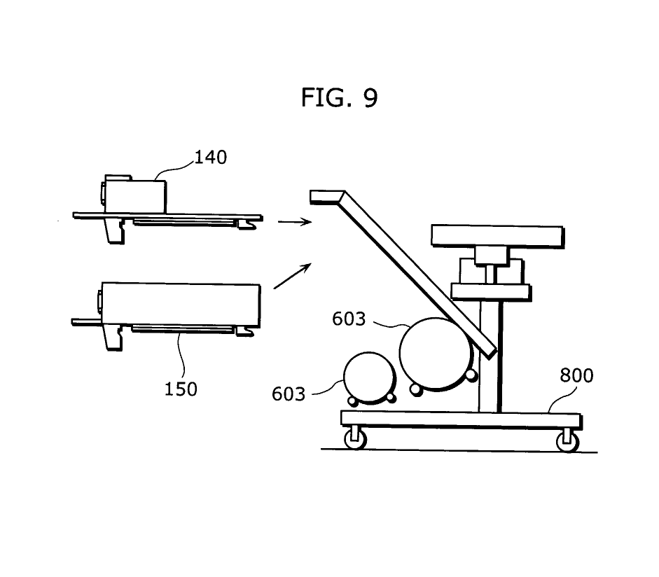

FIG. 9 is a lateral view showing a component feeder carriage 800 for supplying components and the parallely-used feeder 150 and the holder identifying apparatus 140.

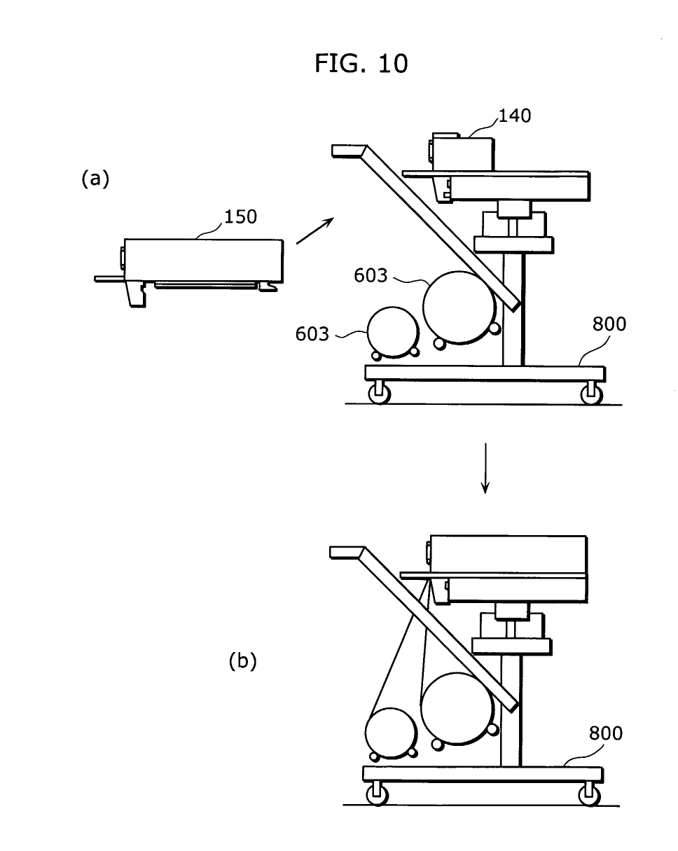

As shown in the diagram, the supply reel 603 around which the component tape for holding the electric components 500 are wound is set in the lower part of the component feeder carriage 800 so as to be rotatable. As shown in (a) in FIG. 10, the holder identifying apparatus 140, the parallely-used feeder 150 and general tape feeders or component feeders are set onto the component feeder carriage 800 so that the holder identifying apparatus 140 in such state can be fitted into a slot installed in the mounter body 101.

As shown in (b) in FIG. 10, the carrier tape 600 pulled out from the supply reel 603 is introduced into the parallely-used feeder 150 or a general tape feeder.

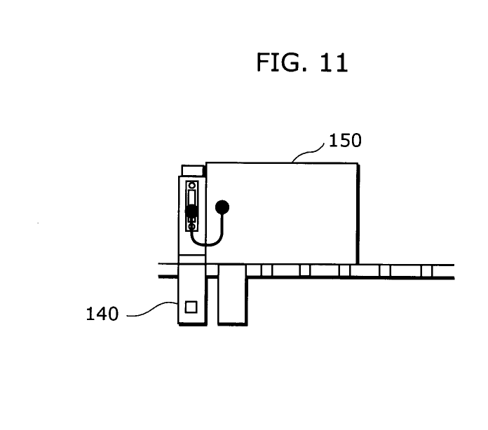

Then, the holder identifying apparatus 140 and the parallely-used feeder 150 which are set to be vertically-paralleled with the component feeder carriage 800 are connected via a cable, as shown in FIG. 11. In this way, the holder identifying apparatus 140 can control the parallely-used feeder 150 based on a command sent from the mounter body 101. Note that the parallely-used feeder 150 is shown in FIG. 11 as the feeder which occupies four slots.

The component feeder carriage 800 on which the holder identifying apparatus 140, the parallely-used feeder 150 into which the carrier tape 600 is introduced as well as the general tape feeders or parts feeders are set, is connected, as a whole, to the mounter body 101.

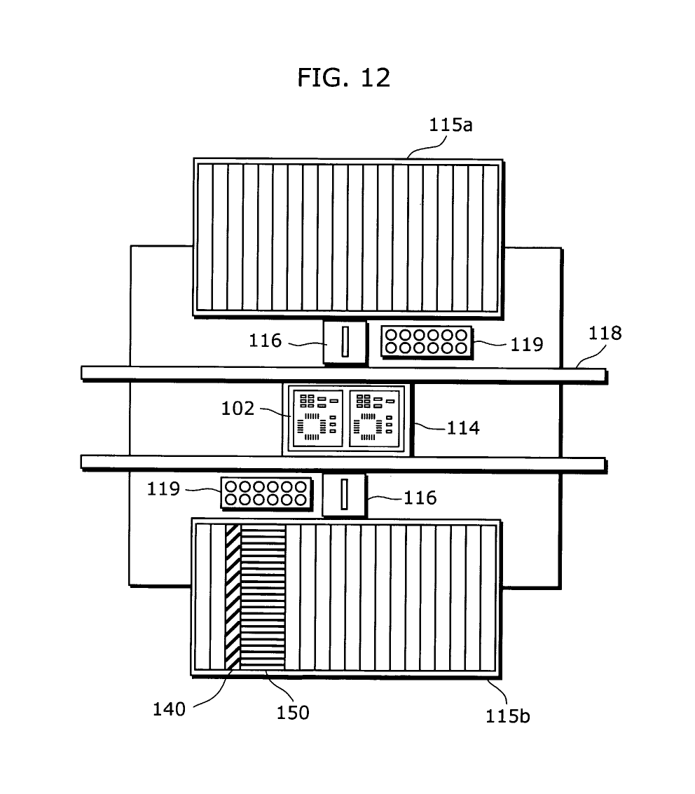

FIG. 12 is a planar view showing the state after the component feeder carriage 800 is coupled to the mounter body 101 although a part of it is not shown in the diagram.

As shown in the diagram, the holder identifying apparatus 140 is fitted to the component supplying unit 115b together with the parallely-used feeder 150 for combined use.

The following describes the operations of the holder identifying apparatus 140, the parallely-used feeder 150 and the mounter body 101.

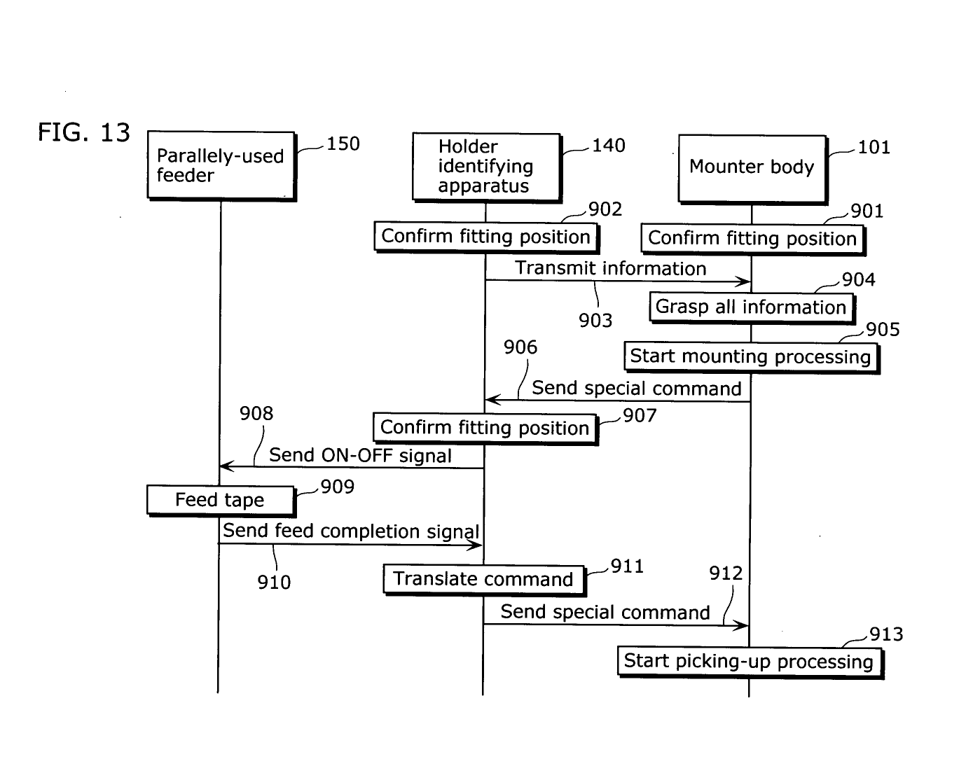

FIG. 13 is a sequence diagram showing the operations of the holder identifying apparatus 140 and the mounter body 101.

As shown in the diagram, once the holder identifying apparatus 140 is fitted into the slot, the holder identifying apparatus 140 and the mounter body 101 both confirm that they are electrically connected with each other (Steps S901 and S902).

After the confirmation on the connection (Steps 901 and S902), the holder identifying apparatus 140 supplies the body control unit 401 with the information regarding the parallely-used feeder 150 that is connected to the apparatus 140 (Step S903).

Examples of such information provided by the holder identifying apparatus 140 may be information about a relative positional relationship between the parallely-used feeder 150 and the holder identifying apparatus 140, and information indicating the number of slots occupied by the parallely-used feeder 150.

The body control unit 401 obtains the information as described above from the holder identifying apparatus 140 so as to grasp the positions to which the holder identifying apparatus 140 and the parallely-used feeder 150 are fitted, and information from the respective general tape feeders or parts feeders so as to grasp the positions in which the feeders are equipped (Step S904).

After having obtained all the information as described above, the mounting processing starts (Step S905). After the start of the mounting, the body control unit 401 sends a special command for control through the communication compliant with a communication specification specific to each of the feeders, based on the information obtained from the respective feeders. The special command is surely transmitted also to the holder identifying apparatus 140 (Step S906).

The holder identifying apparatus 140, having received the command via the special communication unit 442, analyzes the command in the holder control unit 444 (Step S907), and transmits a general control signal in a predetermined timing to the parallely-used feeder 150 that is connected to the holder identifying apparatus 140 (Step S908).

Having received the signal, the parallely-used feeder 150 feeds the tape by driving the stepping motor 451 based on the signal so as to expose the electric component 500 (Step S909). The parallely-used feeder 150 then transmits, to the holder identifying apparatus 140, a signal indicating an end of the predetermined feeding operation by setting up a bit (Step S910).

The holder identifying apparatus 140 having received the signal translates the signal into a command (Step S911), and transmits the command that is translated to the mounter body 101 through the communication compliant with the special specification (Step S912).

Having received the command as well as confirmed that the necessary electric components are placed in the supply positions in the component supplying unit 115, the body control unit 401, starts the operation of picking up the components (Step S913).

Then, the mounter body 101 mounts the electric components on the circuit board according to the general mounting processing, and thus mounts all the electric components on the circuit board by repeating the same operation.

The characteristics of the operations except for the picking up operation which are carried out by the mounter 100 are summarized below.

(1) Nozzle Exchange

In the case where the multi mounting head 112 does not have a nozzle necessary for the next mounting operation, the multi mounting head 112 moves to the nozzle station 119 and performs nozzle exchange. The types of nozzles are, for instance, types S, M and L depending on the size of the component to be picked up.

(2) Picking Up of Components (Step S913)

The multi mounting head 112 moves to the component supplying unit 115 and picks up the electric components placed in pick-up positions in each feeder. In the case where the multi mounting head 112 cannot simultaneously pick up the components as many as the maximum number possibly picked up by the multi mounting head 112, the multi mounting head 112 performs picking up operation for plural times by shifting the pick-up position, and thus, can pick up the maximum number of components. It should be noted that the multi mounting head 112 may pick up the electric components not as many as the maximum number of components.

(3) Recognition Scan

The multi mounting head 112 passes the component recognizing camera 116 at regular speed, scans the images of all the picked-up components, and precisely detects the positions in which the components should be picked up.

(4) Component Mounting

The electric components are mounted one by one onto a circuit board.

All the electric components are mounted onto a circuit board by performing control on each feeder and repeating the operation described in the above (1) through (4).

According to the embodiment, the body control unit 401 of the mounter body 101 communicates with the holder identifying apparatus 140 through the communication compliant with a special specification so as to receive information. The parallely-used feeder 150 and the holder identifying apparatus 140 only perform communication based on the assignment of bits to respective pins. Therefore, it is possible to manufacture the parallely-used feeder 150 in compliance only with a general specification, without disclosing a communication specification used for the communication with the mounter body 101.

In addition, it is possible to reduce the burden of the mounter body 101 by distributing the burden of control since the parallely-used feeder 150 is not directly controlled by the body control unit 401, but is controlled by the holder identifying apparatus 140.

Setting the holder identifying apparatus 140 to occupy one of the slots installed in the mounter body 101, it is possible to easily and visually check the holder identifying apparatus 140 from outside, and thus to intuitively grasp the operation to be carried out by the operator.

Furthermore, there is no need to install a storage apparatus or a control apparatus in each parallely-used feeder 150, and a connector that is generally used can be used as a connector. It is thus possible to reduce the cost of the parallely-used feeder 150, as well as the entire cost by decreasing the necessary number of holder identifying apparatuses 140, which can be realized by flexibly adapting the holder identifying apparatus 140 to different types of parallely-used feeders 150.

Thus, the embodiment of the present invention is described using variations, however, the present invention is not limited to them.

For example, the embodiment describes the mounter 100 as a modular device, however, the holder identifying apparatus 140 and the parallely-used feeder 150 are applicable to other types of mounter such as a rotary device, equipped with a mounting head having a rotation mechanism, which can mount electric components with high speed.

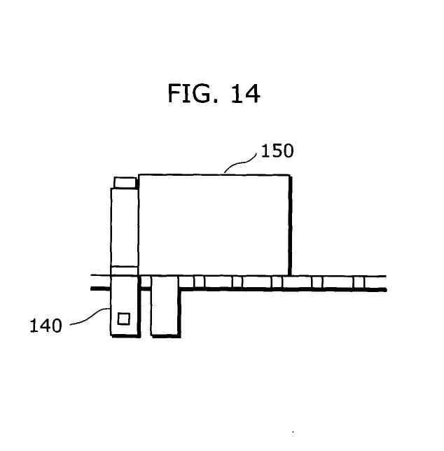

As shown in FIG. 14, the holder identifying apparatus 140 and the parallely-used feeder 150 may not communicate with each other.

In this case, the holder identifying apparatus 140 sends, to the mounter body 101, the information regarding the parallely-used feeder 150 that is installed near the holder identifying apparatus 140. The body control unit 401 performs mounting after having obtained such information and the position in which the parallely-used feeder 150 is installed. The parallely-used feeder 150 independently performs the operation of supplying components without any control command sent from the body control unit 401. Such parallely-used feeder 150 may be characterized in that the feeder provides recognition labels to be mounted onto a circuit board, and only performs a simple operation of placing the next label (i.e. electric component) in a picking-up position as the tape is automatically fed when the label placed in the picking-up position is picked up by the multi mounting head 112.

The following describes a variation of the holder identifying apparatus 140.

(Variation 1)

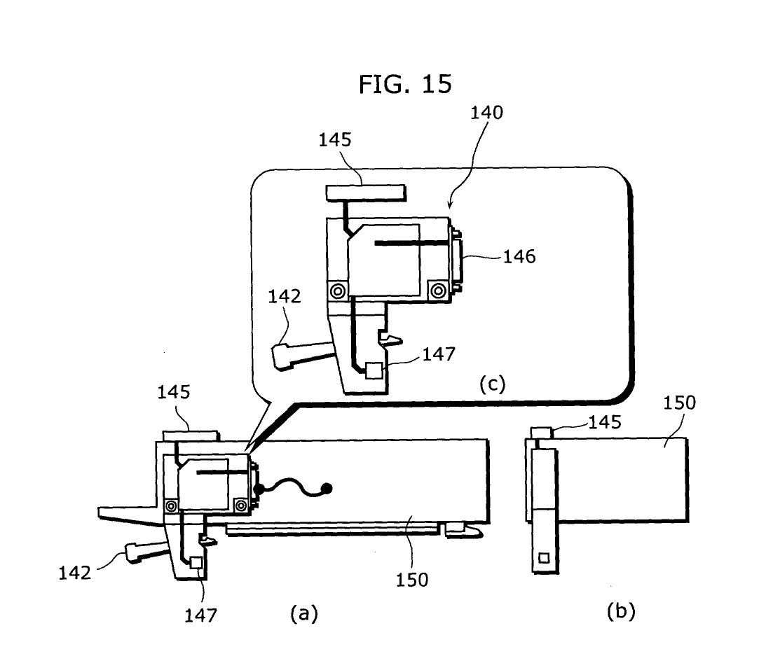

FIG. 15 shows a first variation of the holder identifying apparatus 140. (a) is a lateral view showing the inner state, (b) shows its front view and (c) shows the lateral view in a magnified manner.

The holder identifying apparatus 140 according to the first variation is as same as the holder identifying apparatus 140 described in the embodiment, except that the present apparatus 140 neither includes a component feeder carriage having the form as same as that of a tape feeder so that the feeder carriage is connected to the component supplying unit 115, nor a rail. Instead, the holder identifying apparatus 140 includes: a switch 145 which can give simple instructions to the mounter body 101; a connector 146 connected to a communication cable for communicating with the parallely-used feeder 150; and a connector 147 connected to a communication cable for communicating with the mounter body 101.

Such holder identifying apparatus 140 can be incorporated into the parallely-used feeder 150 in such a manner to be electrically connected to the parallely-used feeder 150.

With the holder identifying apparatus 140 as described above, it is possible to manufacture the parallely-used feeder 150 in such a way that the holder identifying apparatus 140 does not occupy one of the slots installed in the mounter body 101, and that the specification used for the communication with the body control unit 401 and the specification of the specially-formed connector 147 to be connected to the switch 145 and the mounter body 101 are not disclosed.

(Variation 2)

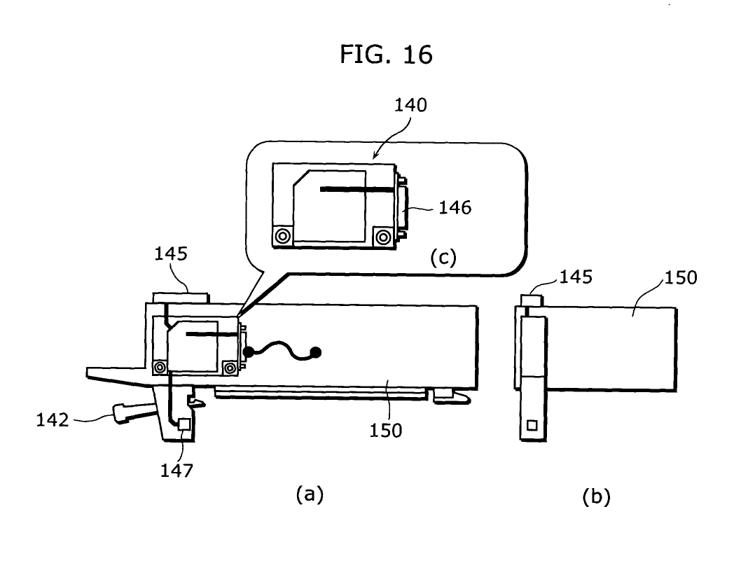

FIG. 16 shows a second variation of the holder identifying apparatus 140. (a) is a lateral view showing the internal state of the apparatus 140, (b) shows its front view, and (c) shows the lateral view in a magnified manner.

The holder identifying apparatus 140 according to the second variation neither includes the component feeder carriage having the form as same as that of a tape feeder so that the feeder carriage is fitted to the component supplying unit 115 or a rail, nor the switch 145 or the connector 147 as described in the first variation. Instead, the present holder identifying apparatus 140 includes a connector 146 connected to a communication cable for communication with the parallely-used feeder 150.

As described in the first variation, the holder identifying apparatus 140 can be incorporated into the parallely-used feeder 150 in such a manner to be electrically connected to the parallely-used feeder 150.

With the holder identifying apparatus 140 as described above, it is possible to manufacture the parallely-used feeder 150 without disclosing the specification used for the communication with the body control unit 401 as well as the specification of the specially-formed connector 147 to be connected to the switch 145 and the mounter body 101.

Although only an exemplary embodiments of this invention has been described in detail above, those skilled in the art will readily appreciate that many modifications are possible in the exemplary embodiment without materially departing from the novel teachings and advantages of this invention. Accordingly, all such modifications are intended to be included within the scope of this invention.

### INDUSTRIAL APPLICABILITY

The present invention is suitable for a mounter which mounts components onto a board, and in particular, for a mounter of which the mounter body performs communication compliant with a special specification for a communication with a feeder intended for component supply.

1. A holder identifying apparatus detachably fitted to a mounter which obtains components from component holders for supplying the components, and mounts the components onto a board, said apparatus comprising:
a holder information storage unit operable to store holder information regarding one of the component holders; and
a communication unit operable to communicate with a mounter body regarding the information stored in said holder information storage unit,
wherein said holder identifying apparatus is used together with the component holder.

2. The holder identifying apparatus according to claim 1, further comprising
a control unit operable to send and receive, to and from the component holder, a control signal through a communication compliant with a predetermined specification, based on a control command from the mounter body.

3. The holder identifying apparatus according to claim 2,
wherein the specification specifies that bits should be assigned to respective signal lines intended for control.

4. The holder identifying apparatus according to claim 1, further comprising
a fitting unit operable to detachably fit the holder identifying apparatus to an attaching/detaching part to which the component holder is fitted.

5. The holder identifying apparatus according to claim 1,
wherein said holder information storage unit is further operable to store collective information for collectively specifying plural component holders.

6. A component supplying method for supplying, with components, a mounter body equipped with the holder identifying apparatus according to claim 1, the mounter body obtaining components from component holders for supplying components, and mounting the components onto a board, said method comprising:
specifying a position in which the holder identifying apparatus is fitted, based on information obtained via an attaching/detaching part into which the holder identifying apparatus is fitted;
obtaining, from the holder information storage unit, holder information regarding one of the component holders; and
specifying a position in which the component holder is fitted, based on the holder information obtained in said obtaining and the fitting position specified in said specifying of the position of the holder identifying apparatus.

7. The component supplying method according to claim 6, further comprising:
sending a control command for controlling the component holder from the mounter body to the holder identifying apparatus, based on the holder information; and
causing the holder identifying apparatus to control the component holder based on the control command.

8. A mounter which obtains components from component holders for supplying components, and mounts the components onto a board, said mounter comprising:
a holder identifying apparatus, detachably fitted to a mounter body of said mounter and used together with one of the component holders, which includes a holder information storage unit operable to store holder information regarding the component holder;
a position specification unit operable to specify a position in which the holder identifying apparatus is fitted, based on information obtained via an attaching/detaching part into which the holder identifying apparatus is fitted;
a holder information obtainment unit operable to obtain holder information from said holder information storage unit; and
a holder position specification unit operable to specify a position in which the component holder is fitted, based on the holder information obtained by said holder information obtainment unit and the fitting position specified by said position specification unit.

9. The mounter according to claim 8, further comprising:
a command sending unit operable to send a control command from said mounter body to said holder identifying apparatus; and
a control unit included in said holder identifying apparatus, which is operable to receive a control signal through a communication compliant with a predetermined specification, based on the control command sent from said mounter body.
